(19) United States
(12) Patent Application Publication
(10) Pub. No.: US 2008/0050872 A1
(43) Pub. Date: Feb. 28, 2008

(54) Fabrication of a high speed RRAM having narrow pulse width programming capabilities

(75) Inventors: Sheng Teng Hsu, Camas, WA (US); Tingkai Li, Vancouver, WA (US)

Correspondence Address: David C. Ripma;Sharp Laboratories of America, Inc., 5750 NW Pacific Rim Boulevard, Camas, WA, 97202, US

(73) Assignee: Sharp Laboratories of America, Inc.

(21) Appl. No.: 11/510,428

(22) Filed: Aug. 24, 2006

(51) Int. Cl. H01L 21/8244; H01L 21/8234

(52) U.S. Cl. 438/238

(57) ABSTRACT

A method of selecting a cathode material and a resistance material for use in a RRAM includes determining the work function of a group of potential resistance materials; determining the work function of a group of potential cathode materials; and selecting a suitable material for the resistance material from the group of potential resistance materials and selecting a suitable material for the cathode material from the group of potential cathode material, wherein the work function of the cathode material is at least 0.2 eV less than the work function of the resistance material.

### FIELD OF THE INVENTION

This invention relates to RRAM devices, and specifically to a RRAM which can be programmed with a very narrow pulse width.

### BACKGROUND OF THE INVENTION

The set resistance state programming pulse width of a RRAM nonvolatile memory resistor may be from lower than 50 ns to wider than 1000 ns. The minimum set pulse width depends on the electrode material, as well as the crystalline properties of the resistance material, such as Pr_{0.7}Ca_{0.3}MnO₃ (PCMO). The reset to a low resistance state is very fast and is little affected by the electrode material. This invention provides general guidance for selection of electrode and resistance materials to be used in the fabrication of RRAM memory cells which may be programmed with a very narrow pulse width.

### SUMMARY OF THE INVENTION

A method of selecting a cathode material and a resistance material for use in a RRAM includes determining the work function of a group of potential resistance materials; determining the work function of a group of potential cathode materials; and selecting a suitable material for the resistance material from the group of potential resistance materials and selecting a suitable material for the cathode material from the group of potential cathode material, wherein the work function of the cathode material is at least 0.2 eV less than the work function of the resistance material.

It is an object of the invention to provide a RRAM having a very narrow pulse width programming capability.

Another object of the invention is to provide a variety of cathode material and resistance materials suitable for use in such a RRAM.

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIG. 1 is a block diagram of the method of the invention.

### DETAILED DESCRIPTION OF THE PREFERRED EMBODIMENTS

The RRAM switching phenomenon is a Jahn-Teller effect, which describes the geometrical distortion of the electron cloud in a non-linear molecule under certain situations. The Jahn-Teller effect does not predict the direction of the distortion, only the presence of an unstable geometry, Jahn et al., Stability of polyatomic molecules in degenerate electronic states, Orbital Degeneracy, Proceedings of the Royal Society of London Series A-Mathematical and Physical Sciences 161, 220-235 (1937). As applied in the field of semiconductors, the Jahn-Teller effect means that when there is a large non-equilibrium electron, valence electrons are localized through the electron-electron interaction to re-arrange the bond length and minimize energy, which in turn stabilizes the bond distortion. As a consequence, the free electron density is reduced and the resistivity increased. During RRAM programming, an electron packet is injected from a cathode material into the resistance material, such as Pr_{0.7}Ca_{0.3}MnO₃ (PCMO), across a cathode-resistance interface, because of the capacitive nature of the resistance material impedance. This electron packet has a high density of electrons not in equilibrium, which causes localization of valence electrons in the electron packet area. This effect increases the resistivity of the memory cell. To reset the memory cell resistance to a low resistance state, an electric field larger than the onset intensity is applied to the high resistivity area, which de-localizes the localized valence electrons.

To set to the memory cell to a high resistance state using a high-speed, narrow pulse width, the cathode material must exhibit high electron injection efficiency, with a built-in field to facilitate electron flow into memory material.

If the work function of the cathode electrode material is smaller than that of the memory resistor material, e.g., less than 4.85 eV for PCMO, electrons accumulate in the memory resistor side of the memory resistor material-cathode material interface. Additionally, there is a built-in field strength which electrons must flow against when entering the memory resistor material. The density of the accumulated electrons and the built-in field strength increases with a decrease in cathode material work function. A set programming electric pulse will inject more electrons to that area, referred to herein as an electron accumulation region, which has a large density of non-equilibrium electron at steady state even after localization of valence electrons. The device may be programmed to a high resistance state only if the width of the programming pulse is relatively wide.

If the work function of the cathode material is larger than the work function of the memory resistor material, the surface of the memory resistor material near the cathode is depleted. The built-in field tends to push any electrons which are injected into the memory resistor material from the cathode material, and the drift and the diffusion currents are in the same direction. Therefore, the electron packet injected into the memory resistor material from the cathode material can transport out of the charge depletion region in a very short time, and the memory resistor may be set to a high resistance state using a very narrow width set pulse.

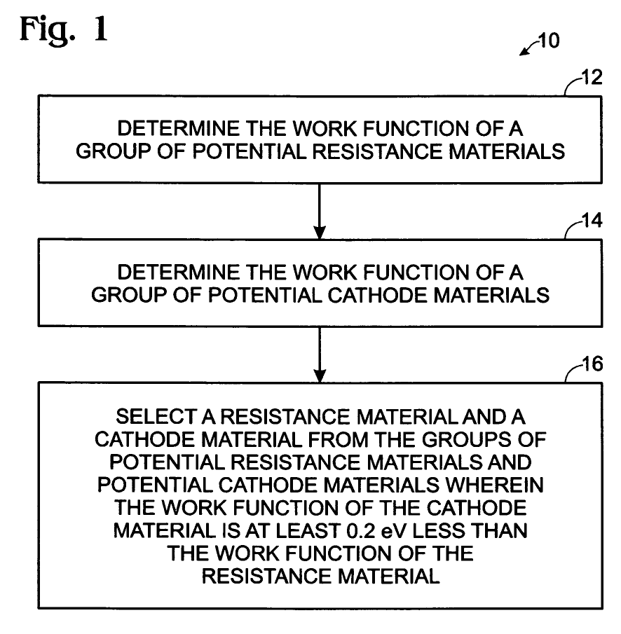

It is concluded that the work function of the materials suitable for cathode electrode of a high speed RRAM memory cell must be greater than 0.2 eV below the work function of the material used as the memory resistor. For cathode material having a work function of at least 0.2 eV below the work function of the memory resistor material, the built-in field and the accumulation electron density is relatively small, and the set pulse width is still reasonably narrow. Referring to FIG. 1, the method of the invention is presented in block diagram form generally at 10. The first step, 12, is to determine the work function of a group of potential resistance materials. Step 14 is to determine the work function of a group of potential cathode materials. Finally, step 16 is to select the resistance material and the cathode materials from their respective groups, wherein the work function of the cathode material is at least 0.2 eV less than the work function of the resistance material. Once the resistance and cathode materials are selected, they may be incorporated into the fabrication process for a RRAM which may be programmed with a very narrow pulse width.

Although the material of the memory resistor cited in this disclosure is PCMO, the method of the invention is equally applicable to other RRAM resistance materials, such as SrZrO₃, SrTiO₃, Ag—PCMO, TiO₃, and other transition metal oxides. It is necessary, when selecting the cathode and resistance material to avoid any non-conductive oxide, which may form at the interface between the cathode material and the memory resistor material, which non-conductive oxide may degrade the cathode electron injection efficiency. Materials which will not readily form an insulating oxide, such as silver, gold or platinum, or a material which forms a conductive oxide, such as iridium, are suitable for cathode electrode application.

Metal suitable for use as the cathode in a high speed PCMO RRAM fabricated according to the method of the invention are listed below.

TABLE 1

| Metal | Work Function |
|---|---|
| Ag | 4.6 |
| Mo | 4.6 |
| Cu | 4.65 |
| Ru (Ruthenium) | 4.71 |
| Os (Osmium) | 4.83 |
| Re (Rhenium) | 4.96 |
| Rh (Rhodium) | 4.98 |
| Co | 5.0 |
| Ni | 5.1 |
| Au | 5.1 |
| Pd | 5.12 |
| Ir | 5.27 |
| Pt | 5.65 |

Thus, a method for fabrication a high speed RRAM has been disclosed. It will be appreciated that further variations and modifications thereof may be made within the scope of the invention as defined in the appended claims.

We claim:

1. A method of selecting a cathode material and a resistance material for use in a RRAM, comprising:
determining the work function of a group of potential resistance materials;
determining the work function of a group of potential cathode materials; and
selecting a suitable material for the resistance material from the group of potential resistance materials and selecting a suitable material for the cathode material from the group of potential cathode material, wherein the work function of the cathode material is at least 0.2 eV less than the work function of the resistance material.

2. The method of claim 1 wherein the cathode material is selected from the group of potential cathode materials which do not readily form a non-conductive oxide at a resistance material-cathode material interface.

3. The method of claim 1 wherein the cathode material has a high electron injection efficiency.
